(19) United States
(12) Patent Application Publication
(10) Pub. No.: US 2017/0231088 A1
(43) Pub. Date: Aug. 10, 2017

(54) DOUBLE-SIDED CIRCUIT SUBSTRATE SUITABLE FOR HIGH-FREQUENCY CIRCUITS

(71) Applicants: NIPPON KAYAKU KABUSHIKI KAISHA, Tokyo (JP); DAIKIN INDUSTRIES, LTD., Osaka (JP)

(72) Inventors: Yasumasa AKATUKA, Tokyo (JP); Shigeru MOTEKI, Tokyo (JP); Hirokazu KOMORI, Osaka (JP); Takeshi INABA, Osaka (JP)

(73) Assignees: NIPPON KAYAKU KABUSHIKI KAISHA, Tokyo (JP); DAIKIN INDUSTRIES, LTD., Osaka (JP)

(21) Appl. No.: 15/501,949

(22) PCT Filed: Aug. 5, 2015
(86) PCT No.: PCT/JP2015/072292

§ 371 Date: Feb. 6, 2017

(30) Foreign Application Priority Data
Aug. 7, 2014 (JP) 2014-161779

(51) Int. Cl. H05K 1/03; H05K 3/46; H05K 3/06; H05K 1/09

(52) U.S. Cl. CPC H05K 1/036; H05K 1/09; H05K 3/4644; H05K 3/06; H05K 2201/015

(57) ABSTRACT

Provided is a double-sided circuit substrate being a laminate of: a composite material comprising a fluorine resin and a glass cloth; and a copper foil having a two-dimensional roughness Ra in a mat surface (a surface that comes in contact with the resin) of less than 0.2 μm. Ideally, a surface of the fluorine resin has an O content of at least 1.0%, as observed using ESCA.

### TECHNICAL FIELD

The present invention relates to a double-sided circuit substrate that has excellent high-frequency transmission characteristics, sufficient adhesion between a copper foil and a resin layer, and also excellent water resistance and dimensional stability, and is suitable for high-frequency circuits.

### BACKGROUND ART

In general, epoxy resins or polyimides are widely used in printed circuit boards. In a high-frequency region where the frequency is several tens of GHz, a laminate of an insulating layer of a fluorine resin formed on a copper foil is mainly used from the viewpoint of dielectric characteristics or hygroscopicity.

The fluorine resin generally does not have a high adhesive force with a metal and therefore requires roughening the surface of the metal for improving the adhesion properties. However, it is known that a high frequency of 1 GHz or larger facilitates transmitting signals to the surface of a metal (skin effect). When metal foil surface serving as a transmission line has large irregularities, electric signals are transmitted, not to the inside of the conductor, but by bypassing the irregular surface, disadvantageously resulting in a large transmission loss. In Examples of Patent Literature 1, those having a surface roughness (Rz) of 0.6 to 0.7 μm are listed. In high-frequency circuits, however, electric signals in the case of, for example, 15 GHz are reportedly transmitted at a depth of 0.5 μm from the metal surface. The depth becomes smaller with increase in frequency. Therefore, this level of surface roughness is inadequate.

Also, the fluorine resin generally has a linear expansion coefficient as high as 100 ppm/° C. or higher and thus presents problems associated with dimensional stability. Patent Literatures 2 to 4 describe a circuit substrate comprising a fluorine resin film and a glass cloth in combination. In Patent Literature 2, a copper foil with an adhesive is used for enhancing adhesion properties. However, the adhesive is usually an epoxy resin and is therefore considered to have poor dielectric characteristics. Hence, this circuit substrate is unsuitable for high-frequency purposes. In Examples of Patent Literature 3, 3EC manufactured by Mitsui Mining & Smelting Co., Ltd. (thickness: 18 μm) is used as a copper foil. This copper foil has a surface roughness Rz of 5 μm or more according to the technical data of the manufacturer. Hence, the circuit substrate is totally unsuitable for use in a high-frequency region. In Patent Literature 4, a copper foil having a surface roughness (Ra) of 0.2 μm and having unroughened surface on both sides is used. For adhesion to an insulating substrate made of a fluorine resin, a composite film of a blend of tetrafluoroethylene-perfluoroalkyl vinyl ether and a liquid-crystal polymer resin is used as an adhesive resin film.

### CITATION LIST

### Patent Literature

Patent Literature 1: JP 2009-246201A
Patent Literature 2: JP H1-317727A
Patent Literature 3: JP H5-269918A
Patent Literature 4: JP 2007-98692A

### SUMMARY OF INVENTION

### Technical Problem

An object of the present invention is to provide a double-sided circuit substrate that has high adhesion between a copper foil having a low surface roughness and a fluorine resin film, is highly dimensionally stable, and can reduce the transmission loss of electric signals in a high-frequency circuit.

### Solution to Problem

The present inventors have found that particular copper foils, fluorine resin films, and glass cloths are placed at predetermined positions and pressure-bonded, whereby a double-sided circuit substrate that has high adhesion properties even to a copper foil having a low surface roughness, consequently has low transmission loss at a high frequency, and further has a low linear expansion coefficient is obtained without the use of an adhesive film. On the basis of this finding, the present invention has been completed.

Specifically, the present invention relates to:

(1) a double-sided circuit substrate which is a laminate of a composite material comprising a fluorine resin and a glass cloth, and a copper foil having a two-dimensional roughness Ra on the matte side (side in contact with the resin) of less than 0.2 μm,

(2) a double-sided circuit substrate comprising n sheets of fluorine resin films and n−1 sheet(s) of glass cloth(s) alternately laminated between two copper foils (n is an integer of 2 or larger and 10 or smaller), wherein the copper foils have a two-dimensional roughness Ra on the matte side (side in contact with the resin) of less than 0.2 μm,

(3) the double-sided circuit substrate according to (1) or (2), wherein the abundance ratio of oxygen atom on the surface of the fluorine resin or the surface of the fluorine resin films is 1.0% or more when observed using ESCA,

(4) the double-sided circuit substrate according to (1) or (2), wherein the fluorine resin films are surface-modified,

(5) the double-sided circuit substrate according to any one of (1) to (4), wherein the copper foil peel strength in a direction of 90 degrees with respect to the double-sided circuit substrate is 0.8 N/mm or larger between the copper foil and the fluorine resin film,

(6) the double-sided circuit substrate according to any of (1) to (5), wherein when the thickness of the substrate except for the copper foils on both sides is defined as X (μm) and the transmission loss of the substrate measured at 20 GHz using a network analyzer is defined as Y (dB/cm), the product of X and Y (X×Y) is 22 or lower, and

(7) the double-sided circuit substrate according to any one of (1) to (6), wherein the fluorine resin films comprise a tetrafluoroethylene-perfluoroalkyl vinyl ether copolymer (PFA).

### Advantageous Effects of Invention

The circuit substrate of the present invention employs a copper foil having a very low surface roughness and as such, has very low transmission loss even in a high-frequency range and is excellent in adhesion properties between a fluorine resin film layer and a metal and dimensional stability even without the use of an adhesive film.

### DESCRIPTION OF EMBODIMENTS

The copper foil used in the present invention has a two-dimensional surface roughness (Ra) preferably in the range of less than 0.2 μm, more preferably in the range of 0.15 μm or less, at least on one side. If the surface roughness is 0.2 μm or more, the transmission loss is increased so that practical performance is not satisfied. The type of the copper foil includes an electrolytic foil and a rolled-out foil, either of which can be used. The thickness of the copper foil is usually 5 to 50 μm, preferably 8 to 40 μm.

The copper foil surface may be untreated copper foil surface, or the surface may be metal-plated, for example, plated with one or more metals selected from nickel, iron, zinc, gold, silver, aluminum, chromium, titanium, palladium, and tin. Also, the untreated copper foil surface or the metal-plated copper foil surface may be treated with an agent such as a silane coupling agent. The metal plating treatment is preferably plating treatment with one or more metals selected from nickel, iron, zinc, gold, and aluminum, more preferably metal plating treatment with nickel or aluminum.

In the specification of the present application, the “matte side of the copper foil” means the side, in contact with the fluorine resin, of each of two copper foils placed on the outermost surface and the back face, respectively, of the double-sided circuit substrate.

The fluorine resin is preferably at least one resin selected from the group consisting of polytetrafluoroethylene [PTFE], polychlorotrifluoroethylene [PCTFE], an ethylene [Et]-TFE copolymer [ETFE], an Et-chlorotrifluoroethylene [CTFE] copolymer, a CTFE-TFE copolymer, a TFE-HFP copolymer (tetrafluoroethylene-hexafluoropropylene copolymer) [FEP], a TFE-PAVE copolymer (tetrafluoroethylene-perfluoroalkyl vinyl ether copolymer) [PFA], and polyvinylidene fluoride [PVdF].

The fluorine resin is more preferably at least one fluorine-containing copolymer selected from the group consisting of PFA and FEP from the viewpoint of electric characteristics (permittivity and dielectric loss tangent), heat resistance, etc.

PFA is a copolymer containing a polymerization unit based on TFE (TFE unit) and a polymerization unit based on PAVE (PAVE unit). In the PFA, examples of the PAVE used include, but are not particularly limited to, a perfluoro unsaturated compound represented by the following general formula (1):

CF₂═CF—ORf¹ (1)

wherein Rf¹ represents a perfluoro organic group. In the present specification, the “perfluoro organic group” means an organic group in which all hydrogen atoms bonded to the carbon atom(s) are replaced with fluorine atoms. The perfluoro organic group may have an ether-binding oxygen atom.

The PAVE is preferably represented by the general formula (1) wherein, for example, Rf¹ is a perfluoroalkyl group having 1 to 10 carbon atoms. The number of carbon atoms in the perfluoroalkyl group is more preferably 1 to 5. Specifically, the PAVE is more preferably at least one member selected from the group consisting of perfluoro(methyl vinyl ether) [PMVE], perfluoro(ethyl vinyl ether) [PEVE], perfluoro(propyl vinyl ether) [PPVE], and perfluoro(butyl vinyl ether) [PBVE], further preferably at least one member selected from the group consisting of PMVE, PEVE, and PPVE, particularly preferably PPVE from the viewpoint of excellent heat resistance.

The PFA usually contains 1 to 10% by mol, preferably 1 to 6% by mol, more preferably 3 to 6% by mol, of the PAVE unit. In the PFA, the total of the TFE unit and the PAVE unit is preferably 90 to 100% by mol with respect to all polymerization units.

The PFA can further contain a polymerization unit based on a monomer copolymerizable with TFE and PAVE. Examples of the monomer copolymerizable with TFE and PAVE include hexafluoropropylene, a vinyl monomer represented by CX¹X²═CX³ (CF₂)ₘX⁴ (wherein X¹, X², and X³ are the same or different and each independently represent a hydrogen atom or a fluorine atom, X⁴ represents a hydrogen atom, a fluorine atom, or a chlorine atom, and m represents an integer of 1 to 10), and an alkyl perfluorovinyl ether derivative represented by CF₂═CF—OCH₂—Rf² (wherein Rf² represents a perfluoroalkyl group having 1 to 5 carbon atoms). The monomer copolymerizable with TFE and PAVE is preferably at least one monomer selected from the group consisting of hexafluoropropylene and an alkyl perfluorovinyl ether derivative represented by CF₂═CF—OCH₂—Rf² (wherein Rf² represents a perfluoroalkyl group having 1 to 5 carbon atoms).

The alkyl perfluorovinyl ether derivative preferably has a perfluoroalkyl group having 1 to 3 carbon atoms as Rf² and is more preferably CF₂═CF—OCH₂—CF₂CF₃.

When the PFA has the polymerization unit based on the monomer copolymerizable with TFE and PAVE, the PFA preferably contains 0 to 10% by mol of the monomer unit derived from the monomer copolymerizable with TFE and PAVE and 90 to 100% by mol in total of the TFE unit and the PAVE unit. More preferably, the PFA contains 0.1 to 10% by mol of the monomer unit derived from the monomer copolymerizable with TFE and PAVE and 90 to 99.9% by mol in total of the TFE unit and the PAVE unit.

FEP is a copolymer containing a polymerization unit based on tetrafluoroethylene (TFE unit) and a polymerization unit based on hexafluoropropylene (HFP unit).

The FEP is not particularly limited and is preferably a copolymer having a molar ratio between the TFE unit and the HFP unit (TFE unit/HFP unit) of 70 to 99/30 to 1. The molar ratio is more preferably 80 to 97/20 to 3. Too small an amount of the TFE unit tends to reduce mechanical properties. Too large an amount of the TFE unit tends to reduce moldability due to too high a melting point.

The FEP is also preferably a copolymer containing 0.1 to 10% by mol of a monomer unit derived from a monomer copolymerizable with TFE and HFP and 90 to 99.9% by mol in total of the TFE unit and the HFP unit. Examples of the monomer copolymerizable with TFE and HFP include PAVE and an alkyl perfluorovinyl ether derivative.

The content of each monomer in the copolymer mentioned above can be calculated by an appropriate combination of NMR, FT-IR, elemental analysis, and fluorescent X-ray analysis according to the type of the monomer. The melt flow rate (MFR) of the fluorine resin is preferably 1.0 g/10 min or higher, more preferably 2.5 g/10 min or higher, further preferably 10 g/10 min or higher. The upper limit of MFR is, for example, 100 g/10 min.

The MFR is a value obtained by measurement under conditions involving a temperature of 372° C. and a load of 5.0 kg in accordance with ASTM D3307 and was also measured according to this method in Examples and Comparative Examples of the specification of the present application.

The melting point of the fluorine resin is preferably 320° C. or lower, more preferably 310° C. or lower. The melting point is preferably 290° C. or higher, more preferably 295° C. or higher, in light of heat resistance and processability in the production of the double-sided substrate.

The melting point is a temperature corresponding to a melting peak at the time of heating at a rate of 10° C./min using a DSC (differential scanning calorimetry) apparatus.

The fluorine resin may contain a filler. Examples of the filler that may be added include, but are not particularly limited to, silica, alumina, low dielectric constant glass, steatite, titanium oxide, strontium titanate, beryllium oxide, aluminum nitride, and boron nitride.

Examples of a method for obtaining each fluorine resin film include the molding of the melt-processable fluorine resin or a composition containing the fluorine resin. Examples of the molding method include methods such as a melt extrusion molding method, a solvent cast method, and a spray method. The fluorine resin film may contain a filler, and the filler that may be contained is the same as the filler that may be added to the fluorine resin.

It is preferred to surface-modify the fluorine resin film used in the present invention, for enhancing the adhesion properties. The surface modification of the fluorine resin film can adopt conventionally practiced discharge treatment such as corona discharge treatment, glow discharge treatment, plasma discharge treatment, or sputtering treatment. For example, surface free energy can be controlled by the introduction of oxygen gas, nitrogen gas, hydrogen gas, or the like into a discharge atmosphere. Alternatively, the surface to be modified is exposed to an atmosphere of an organic compound-containing inert gas, which is an inert gas comprising an organic compound, and discharge is caused by the application of high-frequency voltage to between electrodes, thereby generating active species on the surface. Subsequently, the surface modification can be accomplished by the introduction of the functional group of the organic compound or the graft polymerization of the polymerizable organic compound. Examples of the inert gas include nitrogen gas, helium gas, and argon gas.

Examples of the organic compound in the organic compound-containing inert gas include a polymerizable or nonpolymerizable organic compound containing an oxygen atom, for example: vinyl esters such as vinyl acetate and vinyl formate; acrylic acid esters such as glycidyl methacrylate; ethers such as vinyl ethyl ether, vinyl methyl ether, and glycidyl methyl ether; carboxylic acids such as acetic acid and formic acid; alcohols such as methyl alcohol, ethyl alcohol, phenol, and ethylene glycol; ketones such as acetone and methyl ethyl ketone; carboxylic acid esters such as ethyl acetate and ethyl formate; and acrylic acids such as acrylic acid and methacrylic acid. Among them, vinyl esters, acrylic acid esters, and ketones are preferred, and vinyl acetate and glycidyl methacrylate are particularly preferred, from the viewpoint that the modified surface is less likely to be deactivated, i.e., has a long life, and is easily handled in terms of safety.

The concentration of the organic compound in the organic compound-containing inert gas differs depending on the type thereof, the type of the fluorine resin to be surface-modified, etc., and is usually 0.1 to 3.0% by volume, preferably 0.1 to 1.0% by volume. The discharge conditions can be appropriately selected according to the targeted degree of surface modification, the type of the fluorine resin, the type and concentration of the organic compound, etc. The discharge treatment is usually performed at a charge density in the range of 0.3 to 9.0 W·sec/cm², preferably 0.3 W·sec/cm² or larger and smaller than 3.0 W·sec/cm². The discharge treatment may be conducted at any temperature in the range of 0° C. or higher and 100° C. or lower. The treatment temperature is preferably 80° C. or lower because the film might be stretched or wrinkled, for example.

As for the degree of surface modification, the abundance ratio of O (oxygen atom) is 1.0% or more, preferably 1.2% or more, more preferably 1.8% or more, further preferably 2.5% or more, when observed by ESCA. The upper limit is not particularly limited and is preferably 15% or less in light of productivity and the influence on other physical properties. The abundance ratio of N (nitrogen atom) is not particularly limited and is preferably 0.1% or more. The thickness of one fluorine resin film is usually 10 to 100 μm, more preferably 20 to 80 μm.

A commercially available product can be used as a glass cloth. A glass cloth treated with a silane coupling agent is preferred for enhancing affinity for the fluorine resin. Examples of the material for the glass cloth include E glass, C glass, A glass, S glass, D glass, NE glass, and low-permittivity glass. E glass, S glass, and NE glass are preferred from the viewpoint of easy availability. The weave of fiber may be plain weave or may be twill weave. The thickness of the glass cloth is usually 5 to 90 μm, preferably 10 to 75 μm. A glass cloth thinner than the fluorine resin film used is used.

Examples of a method for preparing a composite of the copper foil, the fluorine resin, and the glass cloth include two methods given below, and the method (i) is preferred in consideration of productivity:

(i) a method of pressure-bonding, under heat, a surface-treated film of the fluorine resin molded in advance with the glass cloth and the copper foil, and
(ii) a method of preparing, under heat, a composite of a melted product of the fluorine resin extruded from a die, and the glass cloth, then surface-treating the composite, and pressure-bonding the surface-treated composite with the copper foil.

The pressure bonding under heat, i.e., thermocompression bonding, can be usually carried out in the range of 250 to 400° C. for 1 to 20 minutes at a pressure of 0.1 to 10 MPa. The thermocompression bonding temperature is preferably lower than 340° C., more preferably 330° C. or lower, because high temperature might cause oozing of the resin or an uneven thickness. The thermocompression bonding may be performed in a batch manner using a press machine or may be performed continuously using a high-temperature laminator. In the case of using the press machine, it is preferred to use a vacuum press machine, for preventing air entrapment and facilitating the entrance of the fluorine resin into the glass cloth. When the fluorine resin is hindered from entering the glass cloth, a plating solution penetrates the glass cloth during the formation of through-holes, easily causing problems such as short between the through-holes.

The surface-treated fluorine resin film cannot sufficiently adhere in itself to the copper foil having a low surface roughness. Thus, the fluorine resin film oozes from the copper foil during thermocompression bonding and has an uneven thickness. By contrast, as mentioned above, its composite with the glass cloth has a sufficiently low linear expansion coefficient, further reduces the oozing of the resin, and exerts high adhesion properties even for the copper foil having a surface roughness Ra of less than 0.2 μm.

The double-sided circuit substrate according to claim 2 comprises n sheets of fluorine resin films and n−1 sheet(s) of glass cloth(s) alternately laminated between two copper foils (n represents an integer of 2 to 10). The value of n is preferably 8 or smaller, more preferably 6 or smaller. The linear expansion coefficient in the XY direction of the dielectric layer of the present invention can be changed by changing the thickness of the fluorine resin films, the type of the glass cloth, and the value of n. The value of the linear expansion coefficient is preferably in the range of 5 to 50 ppm/° C., more preferably in the range of 10 to 40 ppm/° C. If the linear expansion coefficient of the dielectric layer exceeds 50 ppm/° C., the adhesion between the copper foil and the dielectric layer is reduced. Furthermore, problems such as the warpage or waviness of the substrate are more likely to occur after copper foil etching. The fluorine resin films placed above and below the glass cloth have mutually penetrating structures such that the fluorine resin penetrates the glass cloth during hot pressing to fill the voids.

In the dielectric layer comprising the fluorine resin (film) and the glass cloth, it is preferred that a portion or the whole of the glass fiber should exist at a depth of 1 to 50 μm from the surface consisting of the fluorine resin. This existence of a portion or the whole of the glass fiber in the depth range described above can improve copper foil peel strength and further suppress deformation, etc., caused by the heat of a molten solder or the like.

In the present invention, the high-frequency circuit includes not only a circuit that merely transmits only high-frequency signals, but a circuit in which transmission channels that transmit signals other than high-frequency signals, for example, a transmission channel that converts high-frequency signals to low-frequency signals and outputs the generated low-frequency signals to the outside, and a transmission channel for supplying a power to be supplied to drive high-frequency corresponding parts, are also arranged in combination with a high-frequency transmission line in the same plane.

For the double-sided circuit substrate of the present invention, smaller transmission loss is more preferred. The transmission loss is known to be influenced by the thickness of a substrate, and it is difficult to discuss the good or poor characteristics of the substrate only by means of the absolute value of the transmission loss. For the double-sided circuit substrate of the present invention, the thickness of the substrate is also taken into consideration. When the thickness of the substrate except for the copper foils on both sides is defined as X (μm) and the transmission loss of the substrate measured at 20 GHz using a network analyzer is defined as Y (dB/cm), the double-sided circuit substrate preferably satisfies a relationship in which the product of X and Y (X×Y) is 22 or lower, more preferably satisfies a relationship in which the product of X and Y is 20 or lower, further preferably a relationship in which the product of X and Y is 18 or lower.

### EXAMPLES

Hereinafter, the present invention will be described more specifically with reference to Examples and Comparative Examples. However, the present invention is not intended to be limited by Examples below.

(Method for Measuring Copper Foil Surface)

The two-dimensional surface roughness Ra of a copper foil was measured by the stylus method using SE-500 manufactured by Kosaka Laboratory Ltd.

(ESCA Analysis of Fluorine Resin Surface)

Fluorine resin surface was measured by using an X-ray photoelectron spectroscopic apparatus (ESCA-750 manufactured by Shimadzu Corp.).

(Method for Measuring Adhesive Strength Between Copper Foil and PFA Film Layer (Peel Strength))

In accordance with JIS C5016-1994, a copper foil (thickness: 18 μm) was peeled off in a direction of 90° C. with respect to the copper foil removal face at a rate of 50 mm/min, while the peel strength of the copper foil was measured using a tensile tester. The obtained value was used as adhesive strength.

(Method for Measuring Linear Expansion Coefficient of Dielectric Layer)

In accordance with JIS 6911, the linear expansion coefficient of a dielectric layer was measured using TMA (thermomechanical analyzer).

(Method for Measuring Permittivity and Dielectric Loss Tangent)

After copper foil etching of a produced double-sided substrate, its permittivity and dielectric loss tangent were measured at 1 GHz using a cavity resonator (manufactured by Kanto Electronic Application and Development Inc.) and analyzed using a network analyzer (manufactured by Agilent Technologies Japan, Ltd., model: 8719ET).

(Method for Measuring Transmission Loss)

A microstrip line having a length of 10 cm was prepared by etching, and transmission loss was measured at 20 GHz using the network analyzer.

### Example 1

Two unroughened electrolytic copper foils (manufactured by Fukuda Metal Foil & Powder Co., Ltd., product name: CF-T9DA-SV-18) each having a surface roughness Ra of 0.08 μm and a thickness of 18 μm, two tetrafluoroethylene-perfluoroalkyl vinyl ether copolymer (PFA) films (TFE/PPVE=98.5/1.5 (% by mol), MFR: 14.8 g/10 min, melting point: 305° C.), each of which had a thickness of 50 μm, underwent surface treatment on both sides (each film was preheated at 60 to 65° C., and while nitrogen gas containing 0.13% by volume of vinyl acetate was flown in the vicinity of a discharge electrode and a roll-shaped earth electrode (60° C.) of a corona discharge apparatus, the film was continuously passed through the atmosphere along the roll-shaped earth electrode to perform the corona discharge treatment of both sides of the film at a charge density of 1.7 w·s/cm²), and had an abundance ratio of O (oxygen atom) of 2.62% on the surface measured by ESCA surface analysis, and one glass cloth (manufactured by Arisawa Manufacturing Co., Ltd., IPC style name: 1027) having a thickness of 16 μm were prepared, then laminated in the order of copper foil/PFA film/glass cloth/PFA film/copper foil with the matte sides of the copper foils facing the inside, and hot-pressed at 325° C. for 30 minutes using a vacuum press machine to produce a double-sided substrate 1 of the present invention having a thickness of 134 μm.

### Example 2

Double-sided substrate 2 of the present invention having a thickness of 132 μm was produced in the same way as in Example 1 except that: two tetrafluoroethylene-perfluoroalkyl vinyl ether copolymer (PFA) films (TFE/PPVE=98.5/1.5 (% by mol), MFR: 14.8 g/10 min, melting point: 305° C.), each of which underwent surface treatment on one side under the same conditions as in Example 1, had an abundance ratio of O (oxygen atom) of 2.62% on the treated surface measured by ESCA surface analysis, and had an abundance ratio of O (oxygen atom) of 0.61% on the untreated surface measured by ESCA surface analysis were used instead of the PFA films surface-treated on both sides; and the lamination was performed in the order of copper foil/PFA film/glass cloth/PFA film/copper foil such that the matte sides of the copper foils faced the treated surfaces of the PFA films.

### Comparative Example 1

Double-sided substrate 3 having a thickness of 135 μm was produced in the same way as in Example 1 except that the copper foils were changed to roughened electrolytic copper foils (manufactured by Fukuda Metal Foil & Powder Co., Ltd., product name: CF-V9W-SV-18) each having a roughness Ra of 0.39 μm.

### Comparative Example 2

Double-sided substrate 4 having a thickness of 131 μm was produced in the same way as in Example 1 except that two tetrafluoroethylene-perfluoroalkyl vinyl ether copolymer (PFA) films (TFE/PPVE=98.5/1.5 (% by mol), MFR: 14.8 g/10 min, melting point: 305° C.), each of which underwent no surface treatment on any of both sides and had an abundance ratio of O (oxygen atom) of 0.61% measured by ESCA surface analysis were prepared instead of the PFA films surface-treated on both sides.

### Comparative Example 3

Double-sided substrate 5 was produced in the same way as in Example 1 except that the lamination was performed in the order of copper foil/PFA film/PFA film/copper foil excluding the glass cloth.

The copper foil peel strength from the fluorine resin layers was measured for the double-sided substrates 1, 2, 3, 4, and 5. After copper foil etching, the permittivity, dielectric loss tangent, and linear expansion coefficient of each insulator layer were also measured. A microstrip line was further prepared, and transmission loss was measured at 20 GHz. The results are shown in Table 1 below.

TABLE 1

| | | | | Comparative | Comparative | Comparative |
|---|---|---|---|---|---|---|
| | | Example 1 | Example 2 | Example 1 | Example 2 | Example 3 |
| | Unit | Substrate 1 | Substrate 2 | Substrate 3 | Substrate 4 | Substrate 5 |
| Thickness | μm | 134 | 132 | 135 | 131 | 66 |
| Copper foil | N/mm | 2.0 | 2.0 | 2.2 | 0.3 | 1.4 |
| peel strength | | | | | | |
| Permittivity | | 2.31 | 2.31 | 2.31 | 2.31 | 2.06 |
| Dielectric | | 0.0014 | 0.0014 | 0.0014 | 0.0014 | 0.0015 |
| loss tangent | | | | | | |
| Linear | ppm/ | 16 | 16 | 16 | 16 | 130 |
| expansion | ° C. | | | | | |
| coefficient | | | | | | |
| Transmission | dB/cm | 0.15 | 0.15 | 0.23 | Pattern was | Immeasurable |
| loss | | | | | unable to be | |
| | | | | | produced | |

The followings are evident from the table described above.

1. When Examples and Comparative Example 1 were compared, the transmission loss was decreased to approximately 70% in the circuit of the present invention using the copper foils having a small surface roughness.

2. When Examples and Comparative Example 2 were compared, the substrate of the present invention in which the surface-treated fluorine resin films having an abundance ratio of O (oxygen atom) of 1.0% or more on the surface observed using ESCA were in contact with the copper foils had stronger copper foil peel strength. In Comparative Example 2 using the fluorine resin films that underwent no surface treatment, the copper foil peel strength from the fluorine resin was as low as 0.3 N/mm. Thus, the copper foils were easily detached, and a circuit pattern was unable to be produced.

3. When Examples and Comparative Example 3 were compared, the circuit of the present invention using the glass cloth had a smaller linear expansion coefficient and also had larger copper foil peel strength. In Comparative Example 3 using no glass cloth, the copper foil peel strength was as low as 1.4 though the surfaces of the fluorine resin films having an abundance ratio of O (oxygen atom) of 1.0% or more observed using ESCA adhered to the copper foils. In addition, the resin was leaked out of the copper foils during pressing so that the thicknesses were decreased to 66 μm on average. Moreover, the transmission loss was immeasurable due to an uneven thickness.

According to the present invention, a double-sided circuit substrate having a small linear expansion coefficient, large copper foil peel strength, and low transmission loss at a high frequency can be easily produced. Therefore, the present invention is industrially very useful.

1. A double-sided circuit substrate which is a laminate of a composite material comprising a tetrafluoroethylene-perfluoroalkyl vinyl ether copolymer (PFA) and a glass cloth, and a copper foil having a two-dimensional roughness Ra on the matte side (side in contact with the resin) of less than 0.2 μm,
wherein the matte side of the copper foil is in contact with the tetrafluoroethylene-perfluoroalkyl vinyl ether copolymer (PFA) of the composite material.

2. A double-sided circuit substrate comprising n sheets of tetrafluoroethylene-perfluoroalkyl vinyl ether copolymer (PFA) films and n−1 sheet(s) of glass cloth(s) alternately laminated between two copper foils (n is an integer of 2 or larger and 10 or smaller),
wherein the copper foils have a two-dimensional roughness Ra on the matte side (side in contact with the resin) of less than 0.2 μm,
wherein the two copper foils are in contact with the tetrafluoroethylene-perfluoroalkyl vinyl ether copolymer (PFA) films.

3. The double-sided circuit substrate according to claim 1, wherein the abundance ratio of oxygen atom on the surface of the tetrafluoroethylene-perfluoroalkyl vinyl ether copolymer (PFA) is 1.0% or more when observed using ESCA.

4. The double-sided circuit substrate according to claim 1, wherein the tetrafluoroethylene-perfluoroalkyl vinyl ether copolymer (PFA) are surface-modified.

5. The double-sided circuit substrate according to claim 1, wherein the copper foil peel strength in a direction of 90 degrees with respect to the double-sided circuit substrate is 0.8 N/mm or larger between the copper foil and the tetrafluoroethylene-perfluoroalkyl vinyl ether copolymer (PFA) layer.

6. The double-sided circuit substrate according to claim 1, wherein when the thickness of the substrate except for the copper foils on both sides is defined as X (μm) and the transmission loss of the substrate measured at 20 GHz using a network analyzer is defined as Y (dB/cm), the product of X and Y (X×Y) is 22 or lower.

7. (canceled)

8. The double-sided circuit substrate according to claim 2, wherein the abundance ratio of oxygen atom on the surface of the tetrafluoroethylene-perfluoroalkyl vinyl ether copolymer (PFA) films is 1.0% or more when observed using ESCA.

9. The double-sided circuit substrate according to claim 2, wherein the tetrafluoroethylene-perfluoroalkyl vinyl ether copolymer (PFA) films are surface-modified.

10. The double-sided circuit substrate according to claim 2, wherein the copper foil peel strength in a direction of 90 degrees with respect to the double-sided circuit substrate is 0.8 N/mm or larger between the copper foil and the tetrafluoroethylene-perfluoroalkyl vinyl ether copolymer (PFA) layer.

11. The double-sided circuit substrate according to claim 2, wherein when the thickness of the substrate except for the copper foils on both sides is defined as X (μm) and the transmission loss of the substrate measured at 20 GHz using a network analyzer is defined as Y (dB/cm), the product of X and Y (X×Y) is 22 or lower.

12. The double-sided circuit substrate according to claim 1, wherein the tetrafluoroethylene-perfluoroalkyl vinyl ether copolymer (PFA) has a melt flow rate (MFR) of 1.0 g/10 min or higher.

13. The double-sided circuit substrate according to claim 2, wherein the tetrafluoroethylene-perfluoroalkyl vinyl ether copolymer (PFA) has a melt flow rate (MFR) of 1.0 g/10 min or higher.
